(19) United States
(12) Patent Application Publication
(10) Pub. No.: US 2024/0098938 A1
(43) Pub. Date: Mar. 21, 2024

(54) TECHNOLOGIES FOR LOWER DEAD SPACE VAPOR CHAMBER

(71) Applicant: Intel Corporation, Santa Clara, CA (US)

(72) Inventors: Ravishankar Srikanth, Bangalore (IN); Vijith Halestoph R, Bengaluru (IN); Prakash Kurma Raju, Bangalore (IN); Arnab Sen, Whitefield (IN); Isha Garg, Bangalore (IN); Ezekiel Poulose, Chotanikara (IN); Avinash Manu Aravindan, Kerala (IN)

(73) Assignee: Intel Corporation, Santa Clara, CA (US)

(21) Appl. No.: 18/526,948

(22) Filed: Dec. 1, 2023

(51) Int. Cl. H05K 7/20

(52) U.S. Cl. CPC H05K 7/20336; H05K 7/20154; H05K 7/2039

(57) ABSTRACT

Techniques for a vapor chamber with less dead space are disclosed. In an illustrative embodiment, a vapor chamber is formed by folding a sheet and sealing the edges. The edges seal the vapor chamber but take up a relatively large amount of space without allowing for vapor to be transported in that space. The folded edge takes up less space, reducing the overall footprint of the vapor chamber. The vapor chamber with a smaller footprint can allow for, e.g., more space for motherboard area, more space for a battery, and/or a smaller form factor overall.

### BACKGROUND

Vapor chambers are often used to remove heat from components such as processors and move the heat to components such as exhaust fans. Vapor chambers are typically made from a wicking material and structural supports sandwiched between two sheets of metal. The sheets of metal are sealed together along the edges of the vapor chamber. The sealed edge can increase the dimensions of the vapor chamber, but heat is not efficiently transported at the sealed edge.

### BRIEF DESCRIPTION OF THE DRAWINGS

The concepts described herein are illustrated by way of example and not by way of limitation in the accompanying figures. For simplicity and clarity of illustration, elements illustrated in the figures are not necessarily drawn to scale. Where considered appropriate, reference labels have been repeated among the figures to indicate corresponding or analogous elements.

FIG. 1 is a simplified drawing of one embodiment of a compute device with a vapor chamber.

FIG. 2 is a top-down cross-sectional view of the compute device of FIG. 1, showing various components of the compute device including a vapor chamber.

FIG. 3 is an isometric view of one embodiment of a vapor chamber of the compute device of FIG. 1.

FIG. 4 is a cross-sectional view of the vapor chamber of FIG. 3.

FIG. 5 is a cross-sectional view of the vapor chamber of FIG. 3.

FIG. 6 is one embodiment of a flow chart for a method of forming a vapor chamber.

FIG. 7 is a top-down view of one stage of the method of the flow chart of FIG. 6.

FIG. 8 is a top-down view of one stage of the method of the flow chart of FIG. 6.

FIG. 9 is a top-down view of one stage of the method of the flow chart of FIG. 6.

FIG. 10 is a top-down view of one stage of the method of the flow chart of FIG. 6.

FIG. 11 is a top-down view of one stage of the method of the flow chart of FIG. 6.

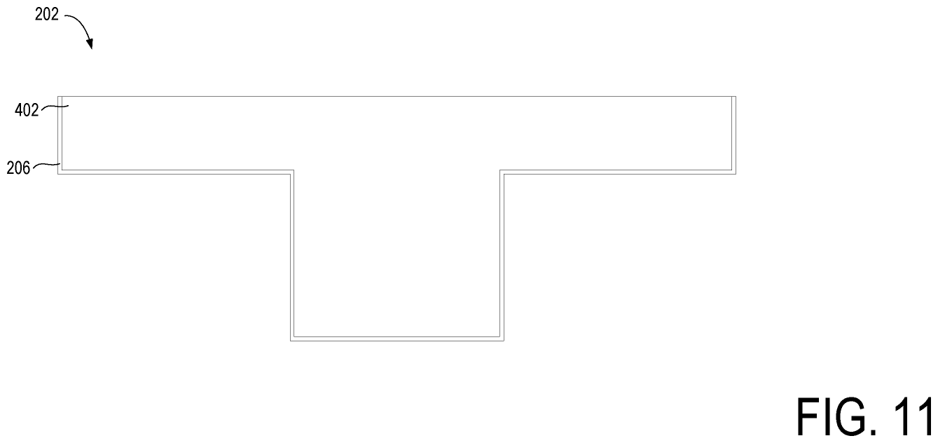

FIG. 12 is a simplified block drawing of at least one embodiment of a compute device.

### DETAILED DESCRIPTION OF THE DRAWINGS

In various embodiments disclosed herein, a compute device may include a vapor chamber made from a folded sheet of metal. The folded edge of the vapor chamber reduces the dead space relative to other edges of the vapor chamber, allowing for more space for, e.g., motherboard routing area, battery, shorter traces between components on the motherboard, and/or a combination thereof.

As used herein, the phrase “communicatively coupled” refers to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, electromagnetic radiation). Examples of components that are communicatively coupled include integrated circuit dies located in the same package that communicate via an embedded bridge in a package substrate and an integrated circuit component attached to a printed circuit board that send signals to or receives signals from other integrated circuit components or electronic devices attached to the printed circuit board.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact, and “coupled” may indicate elements co-operate or interact, but they may or may not be in direct physical or electrical contact. Optical components such as fibers or waveguides may be “connected” if the gap between them is small enough that light can be transferred from one fiber or waveguide to another fiber or waveguide without any intervening optical elements, such as a lens or mirror. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, the central axis of a magnetic plug that is substantially coaxially aligned with a through hole may be misaligned from a central axis of the through hole by several degrees. In another example, a substrate assembly feature, such as a through width, that is described as having substantially a listed dimension can vary within a few percent of the listed dimension.

It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons.

Reference is now made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

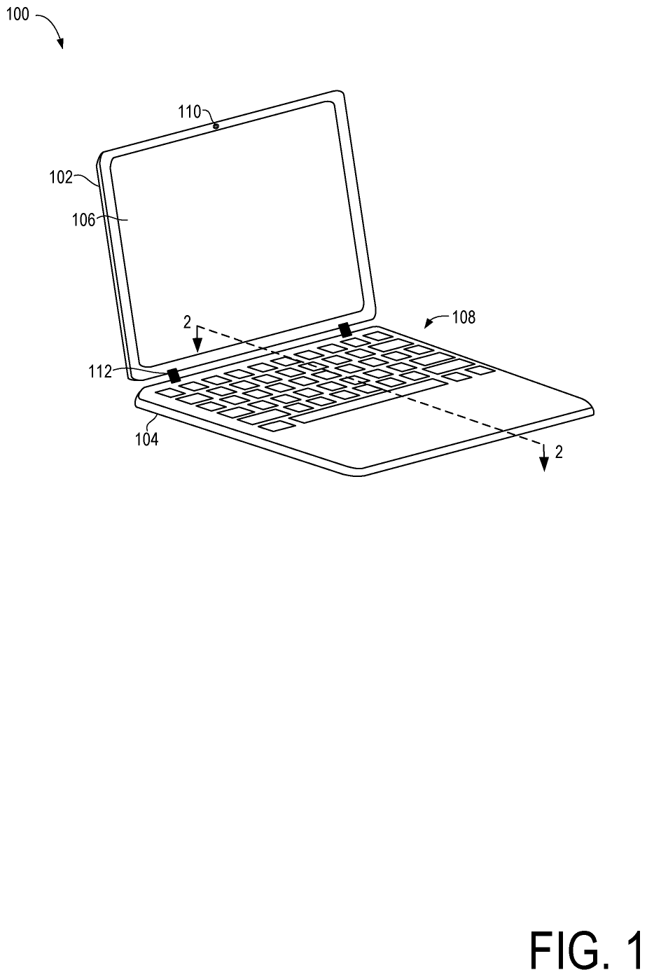

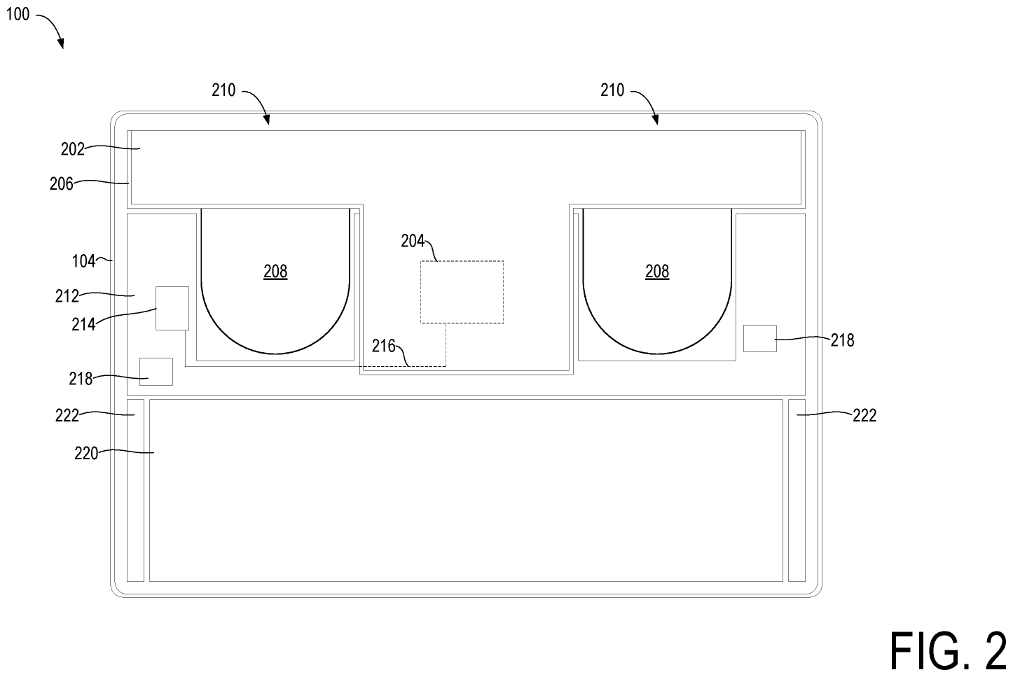

Referring now to FIGS. 1 and 2, an illustrative compute device 100 includes a lid portion 102 and a base portion 104. FIG. 1 shows an isometric view of the compute device 100, and FIG. 2 shows a top-down view of a cross-section of the base portion 104 of the compute device 100. The lid portion 102 includes a display 106, and the base portion 104 includes a keyboard 108. The compute device 100 includes a vapor chamber 202 that can transport heat from a processor 204 to heat sinks 210, where fans 208 can blow air across the heat sinks 210 to remove the heat.

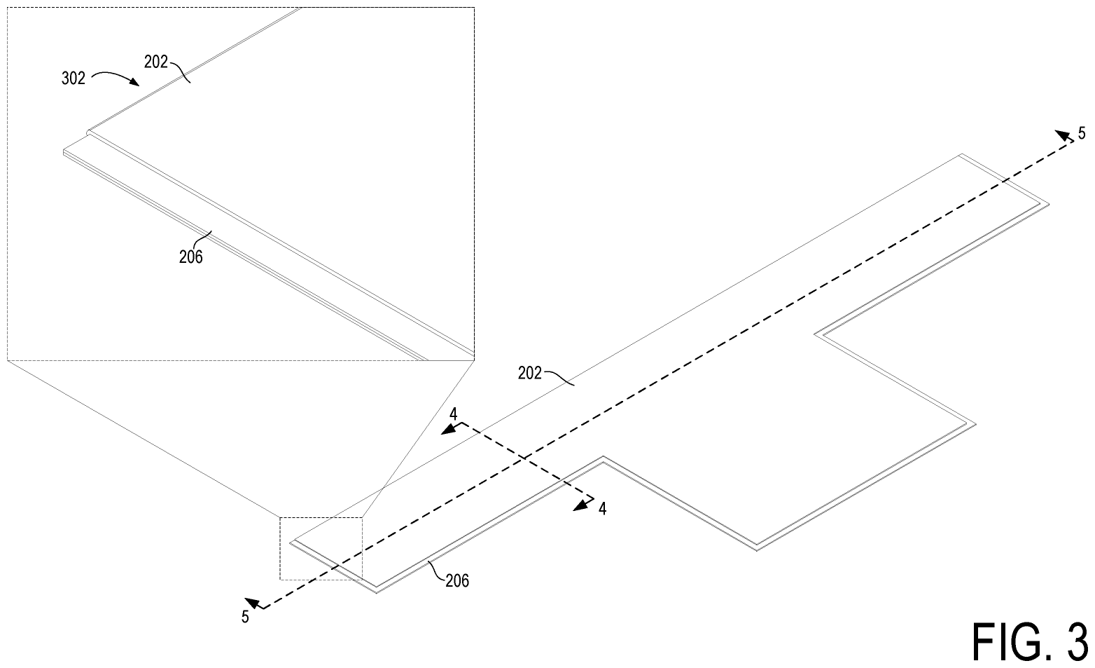

In an illustrative embodiment, the vapor chamber 202 has a seam 206 running along some of the edges of the vapor chamber 202. The vapor chamber 202 also has a fold 302 (see FIG. 3). The vapor chamber 202 may be formed by folding a sheet of metal, as described below in more detail, with the metal being sealed together along the edges to form the seam 206. The seam 206 may have a width of, e.g., 4 millimeters, along which the vapor chamber 202 does not efficiently transfer or conduct heat. In contrast, the fold 302 may have a smaller width, such as 1 millimeter, reducing the space in which the vapor chamber 202 does not perform as well. As a result of replacing the seam 206 at one edge with a fold 302, the vapor chamber 202 takes up less physical space without reducing performance, freeing up space for other components, as described in more detail below.

The illustrative compute device 100 is embodied as a laptop with a clamshell configuration. The illustrative compute device 100 can be in an open configuration (shown in FIG. 1) or a closed configuration, with the lid portion 102 positioned on top of the base portion 104 with the display 106 facing downwards toward the base portion 104. Additionally or alternatively, the compute device 100 may be embodied as a laptop with additional configurations. For example, the compute device 100 may be a laptop with a display that can rotate up to 360°, allowing the compute device 100 to be in a book configuration, a tablet configuration, etc. The compute device 100 may be a 2-in-1 device, with a lid portion 102 that can separate from the base portion 104. In the illustrative embodiment, one or more hinges 112 joins the base portion 104 and the lid portion 102.

The illustrative lid portion 102 has a display 106. The display 106 may be any suitable size and/or resolution, such as a 5-18 inch display, with a resolution from 340×480 to 3820×2400. The display 106 may use any suitable display technology, such as LED, OLED, QD-LED, electronic paper display, etc. The display 106 may be a touchscreen display. The lid portion 102 may also include a camera 110. The camera 110 may include one or more fixed or adjustable lenses and one or more image sensors. The image sensors may be any suitable type of image sensors, such as a CMOS or CCD image sensor. The camera 110 may have any suitable aperture, focal length, field of view, etc. For example, the camera 110 may have a field of view of 60-110° in the azimuthal and/or elevation directions.

FIG. 2 shows a top-down view of a cross-section of the base portion 104 of the compute device 100. The compute device 100 includes the vapor chamber 202, a processor 204, fans 208, heat sinks 210, a motherboard 212, an integrated circuit component 214 connected to the processor 204 by a trace 216 on the motherboard 212, one or more additional integrated circuit components 218, a battery 220, and speakers 222.

In an illustrative embodiment, the vapor chamber 202 is thermally coupled to a processor 204. Additionally or alternatively, in other embodiments, the vapor chamber 202 may be thermally coupled to another integrated circuit component, such as a graphics processing unit (GPU), an xPU, a memory, an application-specific integrated circuit (ASIC), a field-programmable gate array (FPGA), an artificial intelligence (AI) circuit, and/or any other suitable integrated circuit component. In some embodiments, the vapor chamber 202 may be thermally coupled to a heat-generating component that may not be an integrated circuit, such as a power component, a battery, a display, etc., to receive or release heat. The vapor chamber 202 may be thermally coupled to the processor 204 using, e.g., thermal grease, thermal adhesive, a thermal interface material, and/or the like. The components 214, 218 may be embodied as any suitable component, including components similar to the integrated circuit component 204, such as a memory, a processor, an ASIC, an FPGA, etc.

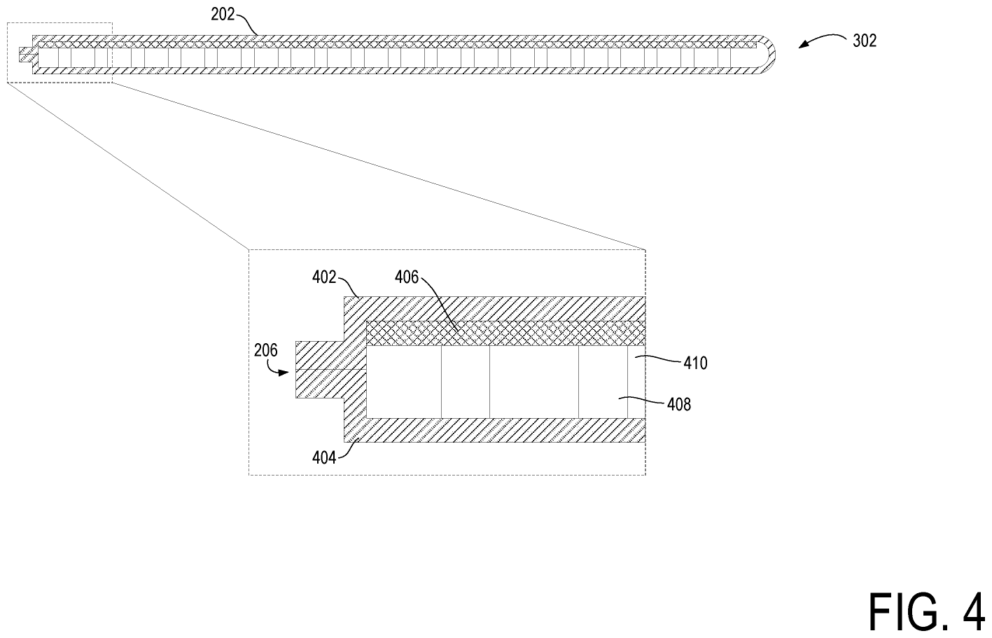

In the illustrative embodiment, the vapor chamber 202 has a “T” shape, with an elongated upper section extending along the length of the base portion 104 over two heat sinks 210, and an elongated lower section extending from the middle of the upper section, as shown in FIG. 2. In use, the vapor chamber 202 transports heat from the processor 204 to one or more heat sinks 210. The illustrative vapor chamber 202 operates by evaporating water or other coolant at the processor 204 and condensing the water or other coolant at the heat sinks 210. The water or other coolant is then recirculated to the processor 204 using a wicking material 406 in the vapor chamber 202 (see FIGS. 4 & 5). In other embodiments, the vapor chamber 202 may have a different space, such as a rectangle, or another shape with various extensions, cut-outs, etc.

The illustrative heat sinks 210 may be embodied as a base thermally coupled to the vapor chamber 202 and several fins extending from the base. The fans 208 are configured to blow air across the fins, transferring heat from the fins of the heat sinks 210 to the air.

The motherboard 212 may be made of any suitable material, such as a fiberglass-based material, FR-4, a glass core circuit board, a printed circuit board, etc. The motherboard 212 may include traces, such as the trace 216, between any suitable components. The traces may be on the top of the motherboard 212, on the bottom of the motherboard 212, or in intermediate layers of the motherboard 212. The motherboard 212 may have any suitable dimensions, such as a length and/or width of 5-400 millimeters and a thickness of 0.5-10 millimeters. The motherboard 212 may have any suitable shape, such as cutouts to accommodate components such as the fans 208.

The battery 220 may be any suitable battery, such as a lithium-ion battery. The battery 220 may have any suitable dimensions, such as a length or width of 50-300 millimeters and a thickness of 1-10 millimeters. The battery 220 may have any suitable capacity, such as 10-200 Watt-hours. In one embodiment, the battery 220 can be increased from an area of 274 millimeters by 110 millimeters and a capacity of 62.5 Watt-hours to an area of 274 millimeters by 114 millimeters and a capacity of 65 Watt-hours due to the lower profile vapor chamber 202 with without the seam 206 along the back edge.

Of course, it should be appreciated that the base portion 104 may include fewer or additional components besides the ones shown in FIG. 2, such as a hard drive, USB ports, power ports, additional circuit board, additional integrated circuit components, etc.

It should be appreciated that the vapor chamber 202 may be a smaller size due to the fold 302 instead of a seam 206 along the back edge of the vapor chamber 202. For example, the vapor chamber 202 may be 1-5 millimeters smaller as a result of the fold 302 in place of the seam 206. The reduced footprint of the vapor chamber 202 can allow for other components in the compute device 100 to be shifted. For example, the vapor chamber 202, motherboard 212, processor 204, fans 208, etc., can be moved several millimeters towards the back of the compute device 100, allowing for more space for the battery 220. Additionally or alternatively, the motherboard 212 can be extended, increasing area for signal routing or placement of integrated circuit components. In some cases, the vapor chamber 202 and fans 208 can be moved close to the back of the compute device 100, allowing for, e.g., the motherboard 212 and the trace 216 to fill in area that would otherwise be taken up by the fans 208, reducing the trace length between the processor 204 and the component 214. In some embodiments, the compute device 100 may have a smaller form factor due to the vapor chamber 202 with a smaller footprint.

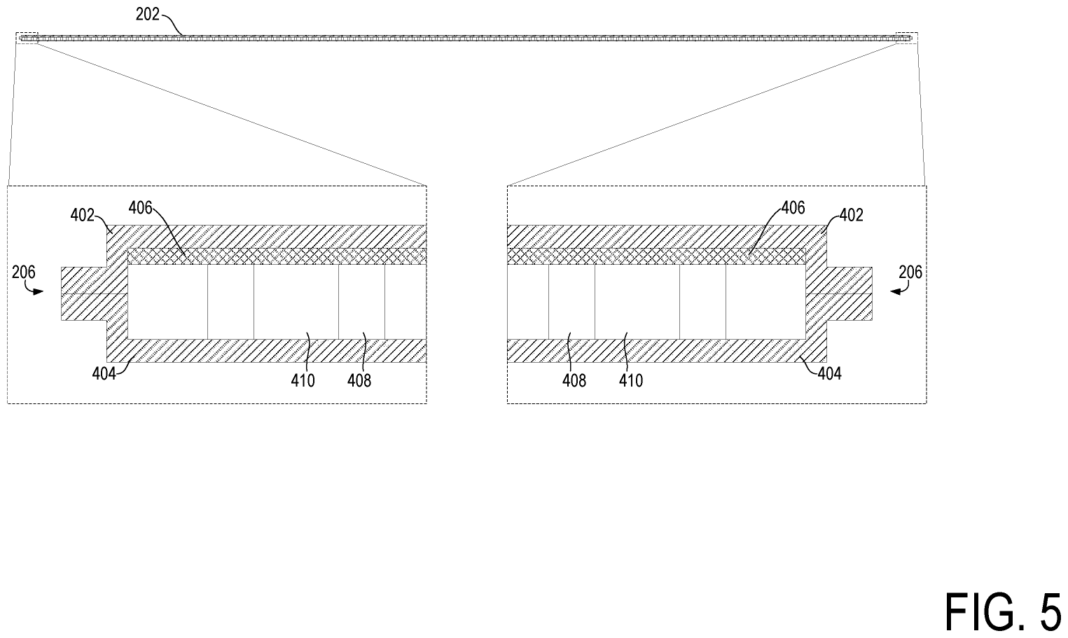

Referring now to FIGS. 3-5, different views of the vapor chamber 202 show the vapor chamber 202 in more detail. FIG. 3 shows an isometric view of the vapor chamber 202, FIG. 4 shows a cross-sectional view of the vapor chamber 202, and FIG. 5 shows another cross-sectional view of the vapor chamber 202. As shown in FIG. 3, the vapor chamber 202 is formed from a single, continuous sheet of material that is folded at the fold 302 and sealed along the seam 206. The vapor chamber 202 includes a top cover 402 and a bottom cover 404. It should be appreciated that, as used herein, “top” cover, “bottom” cover, etc., is merely a label used for convenience and does not imply a particular orientation of the vapor chamber 202. As shown in FIG. 3, the fold 302 at the back edge of the vapor chamber 202 does not include a seam 206, reducing the footprint of the vapor chamber 202. It should be appreciated that, as the area of the seam 206 does not have space for vapor to transfer, the area of the seam 206 does not significantly contribute to transferring heat. Rather, the seam 206 is an area that takes up space but does not significantly improve the performance of the vapor chamber 202. In contrast, the fold 302 takes up relatively little space.

The vapor chamber 202 may be made of any suitable material. In an illustrative embodiment, the vapor chamber 202 is made of copper. Additionally or alternatively, the vapor chamber 202 may be made out of or otherwise include aluminum, titanium, nickel, gold, tin, another metal, carbon, diamond, and/or a combination thereof. The vapor chamber 202 may have any suitable dimensions, such as a length and/or width of 5-500 millimeters, and a thickness of 1-10 millimeters. In one embodiment, the vapor chamber 202 has a width of about 280 millimeters, a length of about 100 millimeters, and a thickness of about 4 millimeters. The top cover 402 and the bottom cover 404 may have any suitable thickness, such as 0.1-2 millimeters.

As shown in FIGS. 4 and 5, the vapor chamber 202 includes pillars 408 for internal structural support to form the cavity 410 in the vapor chamber 202, as well as a wicking material 406 to transport water or other coolant in the vapor chamber 202. The support pillars 408 may be made of the same material as the top cover 402 and bottom cover 404 and/or may be made of a different material. The support pillars 408 may be a separate component that is disposed between the top cover 402 and the bottom cover 404. In some embodiments, some or all of the support structure 408 may be formed monolithically, with the top cover 402 and the bottom cover 404. Similarly, the wicking material 406 may be made of the same material as the top cover 402 and bottom cover 404 and/or may be made of a different material. The wicking material 406 may be a separate component that is disposed between the top cover 402 and the bottom cover 404. In some embodiments, some or all of the wicking material 406 may be formed monolithically with the top cover 402 and the bottom cover 404, such as a complex of channels machined in the top cover 402 and/or the bottom cover 404. In some embodiments, wicking material 406 may be disposed adjacent to the top cover 402 and the bottom cover 404, with the support pillars 408 between two layers of wicking material 406. The wicking material 406 may be embodied as, e.g., a mesh, an etched structure, a woven structure, channels, and/or a combination of the above.

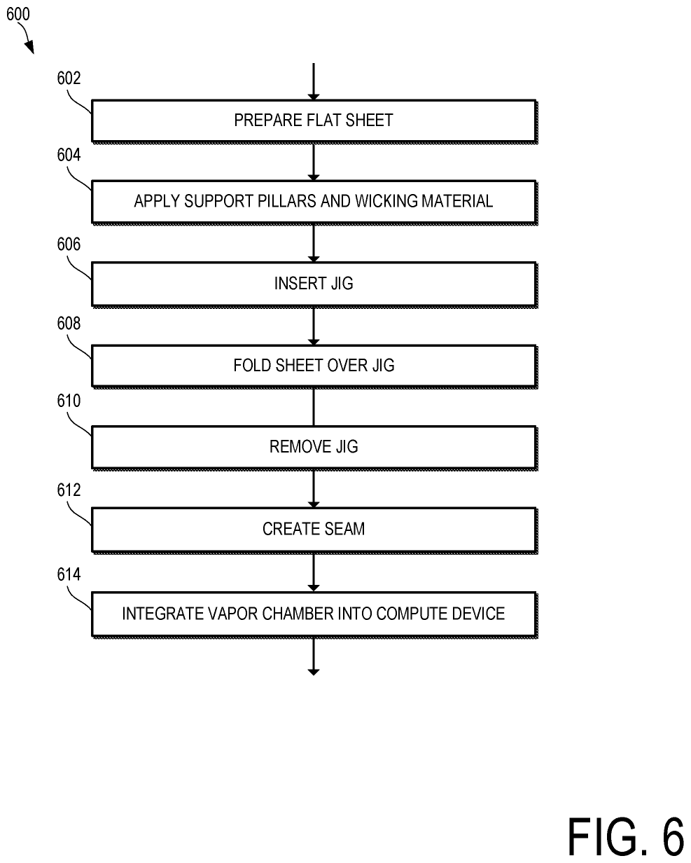

Referring now to FIG. 6, in one embodiment, a flowchart for a method 600 for creating a vapor chamber 202 is shown. The method 600 may be executed by a technician and/or by one or more automated machines. In some embodiments, one or more machines may be programmed to do some or all of the steps of the method 600. Such a machine may include, e.g., a memory, a processor, data storage, etc. The memory and/or data storage may store instructions that, when executed by the machine, causes the machine to perform some or all of the steps of the method 600. It should be appreciated that the method 600 is merely one embodiment of a method to create one embodiment of a vapor chamber 202 and other methods may be used to create any suitable embodiment of the vapor chamber 202. In some embodiments, steps of the method 600 may be performed in a different order than that shown in the flowchart.

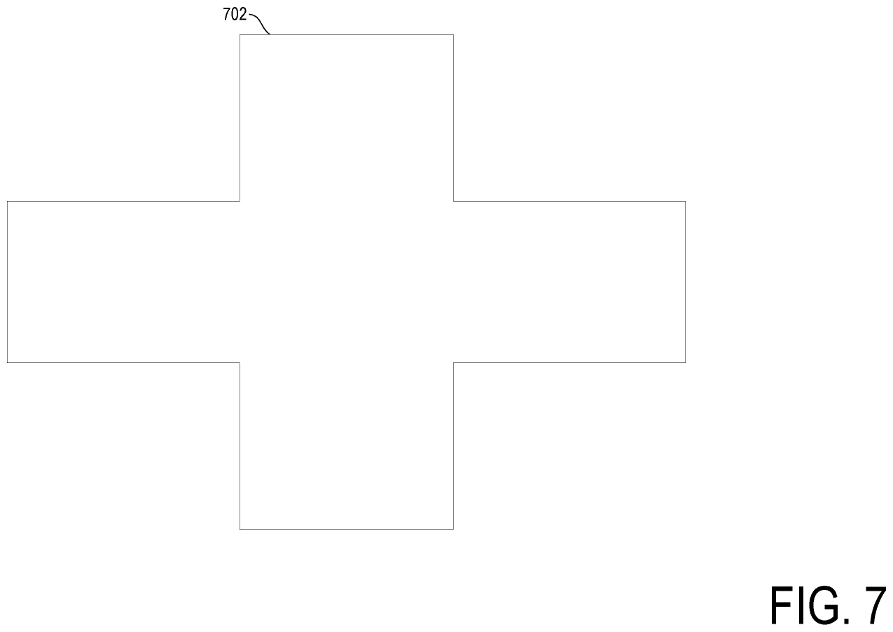

The method 600 begins in block 602, in which a flat sheet 702 is prepared, as shown in FIG. 7. The flat sheet 702 may be cut to size using any suitable approach, such as die cut, laser cut, machining, etc.

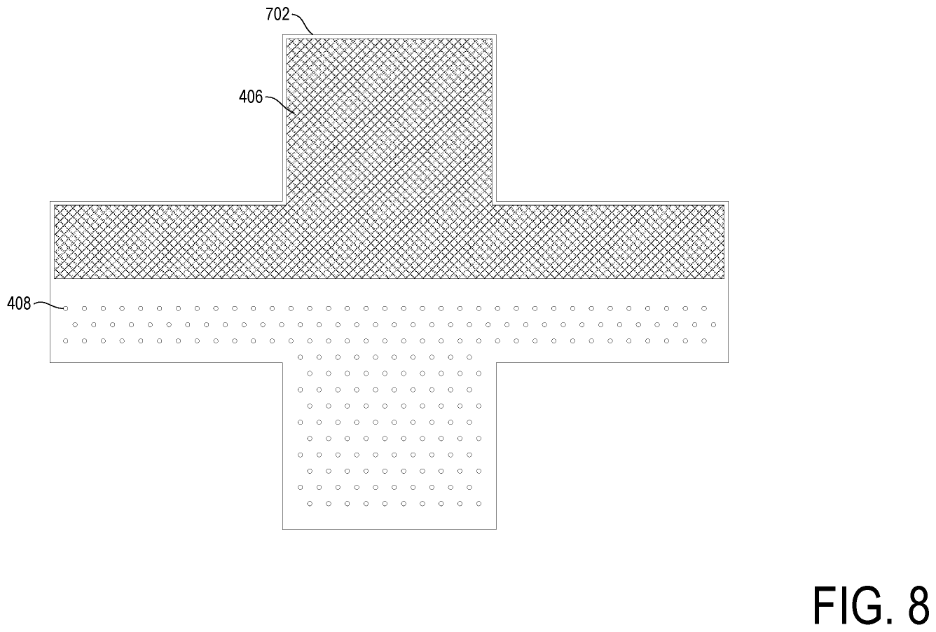

In block 604, support pillars 408 and a wicking material 406 are applied to the flat sheet 702, as shown in FIG. 8. The support pillars 408 and wicking material 406 may be held in place using, e.g., adhesive or epoxy. In some embodiments, the support structure 408 and/or wicking structure 406 may be formed directly on the flat sheet 702, such as by etching, machining, photolithography, etc.

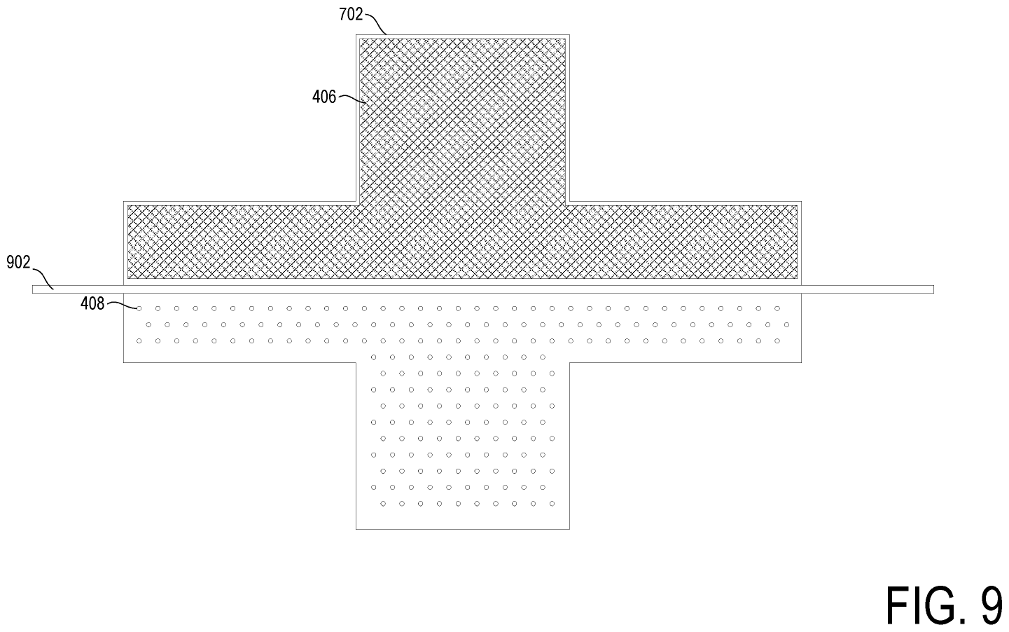

In block 606, a jig 902 is inserted in the middle of the flat sheet 702, as shown in FIG. 9. The jig 902 may be made of any suitable material, such as graphite, metal, plastic, etc. In an illustrative embodiment, the jig 902 is cylindrically shaped with a radius corresponding to the inner radius of the bend 302. For example, the jig 902 may have a diameter of, e.g., 0.2-5 millimeters.

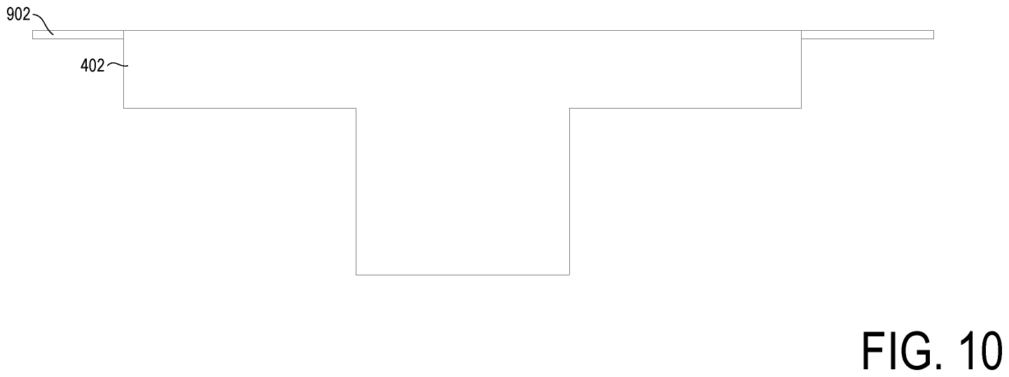

In block 608, the sheet 702 is folded over the jig 902, as shown in FIG. 10. In block 610, the jig 902 is removed. In block 612, the seam 206 is formed on the sheet 702, creating the vapor chamber 202. The seam 206 may be created in any suitable manner, such as by striking the edges of the folded sheet 702 and laser welding, using diffusion bonding, an adhesive, welding, etc. In some embodiments, part of the seam 206 may be cut off using, e.g., laser cutting, mechanical cutting, mechanical grinding, etc. The width of the seam 206 may be reduced from, e.g., about 3 millimeters to about 1.5 millimeters. In general, the width of the seam 206 may be reduced by, e.g., 1-5 millimeters and/or 10-70%. In an illustrative embodiment, one corner may be used to charge the vapor chamber 202 with water or other coolant and then sealed last. In some embodiments, the vapor chamber 202 may undergo testing, such as by testing the Q_{Max} of the vapor chamber 202. In block 614, the vapor chamber 202 is integrated into a compute device 100, as shown in FIG. 2.

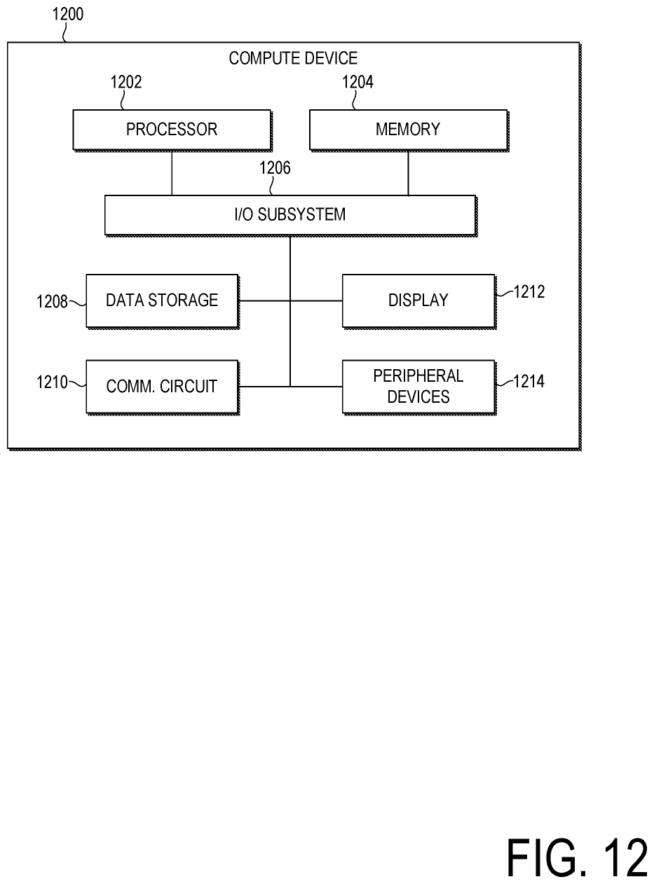

Referring now to FIG. 12, in one embodiment, a compute device 1200 is shown. The compute device 1200 may be embodied as any suitable embodiment of the compute device 100 described above and may include one or more vapor chambers 202. The compute device 1200 may be embodied as any type of compute device. For example, the compute device 1200 may be embodied as or otherwise be included in, without limitation, a server computer, an embedded computing system, a System-on-a-Chip (SoC), a multiprocessor system, a processor-based system, a consumer electronic device, a smartphone, a cellular phone, a desktop computer, a tablet computer, a notebook computer, a laptop computer, a networked computer, a wearable computer, a handset, a messaging device, a camera device, and/or any other compute device. In some embodiments, the compute device 1200 may be located in a data center, such as an enterprise data center (e.g., a data center owned and operated by a company and typically located on company premises), managed services data center (e.g., a data center managed by a third party on behalf of a company), a colocated data center (e.g., a data center in which data center infrastructure is provided by the data center host and a company provides and manages their own data center components (servers, etc.)), cloud data center (e.g., a data center operated by a cloud services provider that host companies applications and data), and an edge data center (e.g., a data center, typically having a smaller footprint than other data center types, located close to the geographic area that it serves).

The illustrative compute device 1200 includes a processor 1202, a memory 1204, an input/output (I/O) subsystem 1206, data storage 1208, a communication circuit 1210, a display 1212, and one or more peripheral devices 1214. In some embodiments, one or more of the illustrative components of the compute device 1200 may be incorporated in, or otherwise form a portion of, another component. For example, the memory 1204, or portions thereof, may be incorporated in the processor 1202 in some embodiments. In some embodiments, one or more of the illustrative components may be physically separated from another component.

The processor 1202 may be embodied as any type of processor capable of performing the functions described herein. For example, the processor 1202 may be embodied as a single or multi-core processor(s), a single or multi-socket processor, a digital signal processor, a graphics processor, a neural network compute engine, an image processor, a microcontroller, or other processor or processing/controlling circuit. Similarly, the memory 1204 may be embodied as any type of volatile or non-volatile memory or data storage capable of performing the functions described herein. In operation, the memory 1204 may store various data and software used during operation of the compute device 1200 such as operating systems, applications, programs, libraries, and drivers. The memory 1204 is communicatively coupled to the processor 1202 via the I/O subsystem 1206, which may be embodied as circuitry and/or components to facilitate input/output operations with the processor 1202, the memory 1204, and other components of the compute device 100. For example, the I/O subsystem 1206 may be embodied as, or otherwise include, memory controller hubs, input/output control hubs, firmware devices, communication links (i.e., point-to-point links, bus links, wires, cables, light guides, printed circuit board traces, etc.) and/or other components and subsystems to facilitate the input/output operations. The I/O subsystem 1206 may connect various internal and external components of the compute device 1200 to each other with use of any suitable connector, interconnect, bus, protocol, etc., such as an SoC fabric, PCIe®, USB2, USB3, USB4, NVMe®, Thunderbolt®, and/or the like. In some embodiments, the I/O subsystem 1206 may form a portion of a system-on-a-chip (SoC) and be incorporated, along with the processor 1202, the memory 1204, and other components of the compute device 100 on a single integrated circuit chip.

The data storage 1208 may be embodied as any type of device or devices configured for the short-term or long-term storage of data. For example, the data storage 1208 may include any one or more memory devices and circuits, memory cards, hard disk drives, solid-state drives, or other data storage devices.

The communication circuit 1210 may be embodied as any type of interface capable of interfacing the compute device 1200 with other compute devices, such as over one or more wired or wireless connections. In some embodiments, the communication circuit 1210 may be capable of interfacing with any appropriate cable type, such as an electrical cable or an optical cable. The communication circuit 1210 may be configured to use any one or more communication technology and associated protocols (e.g., Ethernet, Bluetooth®, Wi-Fi®, WiMAX, near field communication (NFC), etc.). The communication circuit 1210 may be located on silicon separate from the processor 1202, or the communication circuit 1210 may be included in a multi-chip package with the processor 1202, or even on the same die as the processor 1202. The communication circuit 1210 may be embodied as one or more add-in-boards, daughtercards, network interface cards, controller chips, chipsets, specialized components such as a field programmable gate array (FPGA) or application-specific integrated circuit (ASIC), or other devices that may be used by the compute device 1200 to connect with another compute device. In some embodiments, communication circuit 1210 may be embodied as part of a system-on-a-chip (SoC) that includes one or more processors, or included on a multichip package that also contains one or more processors. In some embodiments, the communication circuit 1210 may include a local processor (not shown) and/or a local memory (not shown) that are both local to the communication circuit 1210. In such embodiments, the local processor of the communication circuit 1210 may be capable of performing one or more of the functions of the processor 1202 described herein. Additionally or alternatively, in such embodiments, the local memory of the communication circuit 1210 may be integrated into one or more components of the compute device 1200 at the board level, socket level, chip level, and/or other levels.

The display 1212 may be embodied as any type of display on which information may be displayed to a user of the compute device 1200, such as a touchscreen display, a liquid crystal display (LCD), a thin film transistor LCD (TFT-LCD), a light-emitting diode (LED) display, an organic light-emitting diode (OLED) display, a cathode ray tube (CRT) display, a plasma display, an image projector (e.g., 2D or 3D), a laser projector, a heads-up display, and/or other display technology. The display 1212 may have any suitable resolution, such as 7680×4320, 3840×2160, 1920×1200, 1920×1080, etc.

In some embodiments, the compute device 1200 may include other or additional components, such as those commonly found in a compute device. For example, the compute device 1200 may also have peripheral devices 1214, such as a keyboard, a mouse, a speaker, an external storage device, etc. In some embodiments, the compute device 1200 may be connected to a dock that can interface with various devices, including peripheral devices 1214. The compute device 1200 may include several additional components, such as a battery, one or more antennas, one or more connectors (such as one or more USB2 connectors, one or more USB3 connectors, an SD card slot, a headphone and/or microphone jack, a power connector, etc.), etc. Each of those various components may be in the lid portion 102 and/or the base portion 104, as appropriate.

### Examples

Illustrative examples of the technologies disclosed herein are provided below. An embodiment of the technologies may include any one or more, and any combination of, the examples described below.

Example 1 includes a compute device comprising one or more integrated circuit components; and a vapor chamber thermally coupled to the one or more integrated circuit components, wherein the vapor chamber comprises a continuous sheet, wherein the continuous sheet is folded to form a top cover of the vapor chamber and a bottom cover of the vapor chamber, wherein the top cover and the bottom cover meet at one or more edges of the vapor chamber to form a seam.

Example 2 includes the subject matter of Example 1, and wherein the vapor chamber comprises copper.

Example 3 includes the subject matter of any of Examples 1 and 2, and wherein the vapor chamber comprises aluminum.

Example 4 includes the subject matter of any of Examples 1-3, and wherein the vapor chamber comprises titanium.

Example 5 includes the subject matter of any of Examples 1-4, and wherein the vapor chamber has an elongated top section and a bottom section extending from the top section to form a T shape.

Example 6 includes the subject matter of any of Examples 1-5, and wherein the continuous sheet is folded at an edge of the elongated top section.

Example 7 includes the subject matter of any of Examples 1-6, and wherein the vapor chamber has a rectangular shape.

Example 8 includes the subject matter of any of Examples 1-7, and wherein the one or more integrated circuit components comprises a processor, further comprising one or more heat sinks thermally coupled to the vapor chamber; and one or more fans to blow air across the one or more heat sinks.

Example 9 includes the subject matter of any of Examples 1-8, and further including a plurality of support pillars disposed between the top cover and the bottom cover; and a mesh disposed between the top cover and the bottom cover.

Example 10 includes a vapor chamber comprising a continuous sheet, wherein the continuous sheet is folded to form a top cover of the vapor chamber and a bottom cover of the vapor chamber, wherein the top cover and the bottom cover meet at one or more edges of the vapor chamber to form a seam; a plurality of support pillars disposed between the top cover and the bottom cover; and a mesh disposed between the top cover and the bottom cover.

Example 11 includes the subject matter of Example 10, and wherein the continuous sheet comprises copper.

Example 12 includes the subject matter of any of Examples 10 and 11, and wherein the continuous sheet comprises aluminum.

Example 13 includes the subject matter of any of Examples 10-12, and wherein the continuous sheet comprises titanium.

Example 14 includes the subject matter of any of Examples 10-13, and wherein the vapor chamber has an elongated top section and a bottom section extending from the top section to form a T shape.

Example 15 includes the subject matter of any of Examples 10-14, and wherein the continuous sheet is folded at an edge of the elongated top section.

Example 16 includes the subject matter of any of Examples 10-15, and wherein the vapor chamber has a rectangular shape.

Example 17 includes a compute device comprising one or more integrated circuit components; and a vapor chamber thermally coupled to the one or more integrated circuit components, wherein the vapor chamber has an edge without a seam.

Example 18 includes the subject matter of Example 17, and wherein the vapor chamber comprises copper.

Example 19 includes the subject matter of any of Examples 17 and 18, and wherein the vapor chamber comprises aluminum.

Example 20 includes the subject matter of any of Examples 17-19, and wherein the vapor chamber comprises titanium.

Example 21 includes the subject matter of any of Examples 17-20, and wherein the vapor chamber has an elongated top section and a bottom section extending from the top section to form a T shape.

Example 22 includes the subject matter of any of Examples 17-21, and wherein the vapor chamber comprises a continuous sheet that is folded at an edge of the elongated top section.

Example 23 includes the subject matter of any of Examples 17-22, and wherein the vapor chamber has a rectangular shape.

Example 24 includes the subject matter of any of Examples 17-23, and wherein the one or more integrated circuit components comprises a processor, further comprising one or more heat sinks thermally coupled to the vapor chamber; and one or more fans to blow air across the one or more heat sinks.

Example 25 includes the subject matter of any of Examples 17-24, and further including a plurality of support pillars disposed between a top cover of the vapor chamber and a bottom cover of the vapor chamber; and a mesh disposed between the top cover and the bottom cover.

Example 26 includes a method comprising disposing support structure on a sheet of metal; disposing wicking material on the sheet of metal; folding the sheet of metal to form a top cover and bottom cover, the bottom cover and top cover joined at a fold; and sealing the top cover to the bottom cover to form a vapor chamber.

Example 27 includes the subject matter of Example 26, and wherein folding the sheet of metal comprising placing a jig on the sheet of metal; folding the sheet of metal around the jig; and removing the jig.

Example 28 includes the subject matter of any of Examples 26 and 27, and wherein the jig comprises graphite.

Example 29 includes the subject matter of any of Examples 26-28, and wherein sealing the top cover of the bottom cover comprises striking the top cover or the bottom cover or both; and laser welding the top cover to the bottom cover.

Example 30 includes the subject matter of any of Examples 26-29, and further including charging the vapor chamber with coolant before fully sealing the top cover to the bottom cover.

Example 31 includes the subject matter of any of Examples 26-30, and wherein sealing the top cover to the bottom cover to form a vapor chamber comprises forming a seam, further comprising removing at least part of the seam to reduce a width of the seam.

Example 32 includes the subject matter of any of Examples 26-31, and wherein removing at least part of the seam comprises laser cutting the seam.

Example 33 includes the subject matter of any of Examples 26-32, and wherein removing at least part of the seam comprises reducing the width of the seam by at least 40%.

Example 34 includes the subject matter of any of Examples 26-33, and wherein the vapor chamber comprises copper.

Example 35 includes the subject matter of any of Examples 26-34, and wherein the vapor chamber comprises aluminum.

Example 36 includes the subject matter of any of Examples 26-35, and wherein the vapor chamber comprises titanium.

Example 37 includes the subject matter of any of Examples 26-36, and wherein the vapor chamber has an elongated top section and a bottom section extending from the top section to form a T shape.

Example 38 includes the subject matter of any of Examples 26-37, and wherein the vapor chamber has a rectangular shape.

Example 39 includes the subject matter of any of Examples 26-38, and further including thermally coupling the vapor chamber to one or more integrated circuit components.

1. A compute device comprising:
one or more integrated circuit components; and
a vapor chamber thermally coupled to the one or more integrated circuit components, wherein the vapor chamber comprises a continuous sheet, wherein the continuous sheet is folded to form a top cover of the vapor chamber and a bottom cover of the vapor chamber, wherein the top cover and the bottom cover meet at one or more edges of the vapor chamber to form a seam.

2. The compute device of claim 1, wherein the vapor chamber comprises copper.

3. The compute device of claim 1, wherein the vapor chamber comprises aluminum.

4. The compute device of claim 1, wherein the vapor chamber comprises titanium.

5. The compute device of claim 1, wherein the vapor chamber has an elongated top section and a bottom section extending from the top section to form a T shape.

6. The compute device of claim 5, wherein the continuous sheet is folded at an edge of the elongated top section.

7. The compute device of claim 1, wherein the one or more integrated circuit components comprises a processor, further comprising:
one or more heat sinks thermally coupled to the vapor chamber; and
one or more fans to blow air across the one or more heat sinks.

8. The compute device of claim 1, further comprising:
a plurality of support pillars disposed between the top cover and the bottom cover; and
a mesh disposed between the top cover and the bottom cover.

9. A vapor chamber comprising:
a continuous sheet, wherein the continuous sheet is folded to form a top cover of the vapor chamber and a bottom cover of the vapor chamber, wherein the top cover and the bottom cover meet at one or more edges of the vapor chamber to form a seam;
a plurality of support pillars disposed between the top cover and the bottom cover; and
a mesh disposed between the top cover and the bottom cover.

10. The vapor chamber of claim 9, wherein the continuous sheet comprises copper.

11. The vapor chamber of claim 9, wherein the vapor chamber has an elongated top section and a bottom section extending from the top section to form a T shape.

12. The vapor chamber of claim 11, wherein the continuous sheet is folded at an edge of the elongated top section.

13. A method comprising:
disposing support structure on a sheet of metal;
disposing wicking material on the sheet of metal;
folding the sheet of metal to form a top cover and bottom cover, the bottom cover and top cover joined at a fold; and
sealing the top cover to the bottom cover to form a vapor chamber.

14. The method of claim 13, wherein folding the sheet of metal comprising:
placing a jig on the sheet of metal;
folding the sheet of metal around the jig; and
removing the jig.

15. The method of claim 14, wherein the jig comprises graphite.

16. The method of claim 13, wherein sealing the top cover of the bottom cover comprises:
striking the top cover or the bottom cover or both; and
laser welding the top cover to the bottom cover.

17. The method of claim 16, further comprising: charging the vapor chamber with coolant before fully sealing the top cover to the bottom cover.

18. The method of claim 13, wherein the vapor chamber has an elongated top section and a bottom section extending from the top section to form a T shape.

19. The method of claim 13, wherein the vapor chamber has a rectangular shape.

20. The method of claim 13, wherein sealing the top cover to the bottom cover to form a vapor chamber comprises forming a seam, further comprising removing at least part of the seam to reduce a width of the seam.
